(19) United States
(12) Patent Application Publication
(10) Pub. No.: US 2025/0234638 A1
(43) Pub. Date: Jul. 17, 2025

(54) SEMICONDUCTOR DEVICES

(71) Applicant: Samsung Electronics Co., Ltd., Suwon-si (KR)

(72) Inventors: Seungho Jung, Suwon-si (KR); Kihyung Ko, Suwon-si (KR); Joon Ki, Suwon-si (KR); Gayeun Kim, Suwon-si (KR); Kanguk Jung, Suwon-si (KR); Jihoon Cha, Suwon-si (KR)

(21) Appl. No.: 18/783,070

(22) Filed: Jul. 24, 2024

(30) Foreign Application Priority Data
Jan. 16, 2024 (KR) 10-2024-0006507

(51) Int. Cl. H01L 27/092; H01L 21/8238; H01L 29/06; H01L 29/423; H01L 29/66; H01L 29/775; H01L 29/786

(52) U.S. Cl. CPC H10D 84/85; H10D 30/014; H10D 30/43; H10D 30/6735; H10D 30/6757; H10D 62/121; H10D 64/017; H10D 84/0188; H10D 84/038

(57) ABSTRACT

A semiconductor device includes a first active region and a second active region on a substrate and spaced apart from each other; a first gate electrode crossing the first active region; a second gate electrode crossing the second active region; and a gate isolation layer between the first and second gate electrodes, wherein the second gate electrode includes a first conductive layer and a second conductive layer stacked in order, the first gate electrode includes the second conductive layer and is spaced apart from the first conductive layer, a first side surface of the gate isolation layer faces the first gate electrode and is in contact with the second conductive layer, and a second side surface of the gate isolation layer faces the second gate electrode and is in contact with the first conductive layer and the second conductive layer in order from a lower portion.

### CROSS-REFERENCE TO RELATED APPLICATION(S)

This application claims benefit of priority to Korean Patent Application No. 10-2024-0006507 filed on Jan. 16, 2024 in the Korean Intellectual Property Office, the disclosure of which is incorporated herein by reference in its entirety.

### BACKGROUND

Example embodiments in the present disclosure relate to a semiconductor device.

As demand for high performance, high speed, and/or multifunctionality of a semiconductor device increases, integration density of a semiconductor device has increased. In manufacturing a semiconductor device having a fine pattern in response to the trend for high integration density of a semiconductor device, it may be necessary to implement patterns having a fine width or a fine spacing. Also, to overcome limitations in operating properties due to reduction of a size of a planar MOSFET (a metal oxide semiconductor FET), there have been efforts to develop a semiconductor device including a FinFET including a three-dimensional channel.

### SUMMARY

An example embodiment of the present disclosure is to provide a semiconductor device having improved reliability and mass productivity.

According to an example embodiment of the present disclosure, a semiconductor device includes a substrate having a first region and a second region; a first active region extending in a first direction on the first region; a second active region extending in the first direction on the second region; a device isolation layer defining the first and second active regions in the substrate; a first gate electrode crossing the first active region and extending in a second direction; a second gate electrode crossing the second active region and extending in the second direction; a plurality of first channel layers spaced apart from each other in a third direction perpendicular to an upper surface of the substrate and surrounded by the first gate electrode on the first active region; a plurality of second channel layers spaced apart from each other in the third direction and surrounded by the second gate electrode on the second active region; gate insulating layers between the plurality of first channel layers and the first gate electrode and between the plurality of second channel layers and the second gate electrode; and a gate isolation layer between the first gate electrode and the second gate electrode, the gate isolation layer including an insulating material, wherein the second gate electrode includes a first conductive layer and a second conductive layer stacked in order from the plurality of second channel layers, wherein the first gate electrode includes the second conductive layer covering the plurality of first channel layers and is spaced apart from the first conductive layer, and wherein each of first and second side surfaces of the gate isolation layer in the second direction is in contact with the second conductive layer.

According to an example embodiment of the present disclosure, a semiconductor device includes a first active region and a second active region extending in a first direction on a substrate, spaced apart from each other in a second direction intersecting the first direction, the first and second active regions including impurities of different conductivity types from each other; a first gate electrode crossing the first active region and extending in the second direction; a second gate electrode crossing the second active region and extending in the second direction; and a gate isolation layer between the first and second gate electrodes, wherein the second gate electrode includes a first conductive layer and a second conductive layer stacked in order, wherein the first gate electrode includes the second conductive layer and is spaced apart from the first conductive layer, wherein a first side surface of the gate isolation layer in the second direction faces the first gate electrode and is in contact with the second conductive layer, and wherein a second side surface opposing the first side surface of the gate isolation layer faces the second gate electrode and is in contact with the first conductive layer and the second conductive layer in order from a lower portion of the gate isolation layer.

According to an example embodiment of the present disclosure, a semiconductor device includes a first active region and a second active region extending in a first direction on a substrate, spaced apart from each other in a second direction intersecting the first direction, the first and second active regions including impurities of different conductivity types from each other; a first gate electrode crossing the first active region and extending in the second direction; a second gate electrode crossing the second active region and extending in the second direction; and a gate isolation layer between the first and second gate electrodes, wherein the second gate electrode includes a first conductive layer, a second conductive layer, and a third conductive layer stacked in order, wherein the first gate electrode includes the second conductive layer and the third conductive layer stacked in order, and is spaced apart from the first conductive layer, and wherein each of side surfaces of the gate isolation layer in the second direction is in contact with the second conductive layer and is spaced apart from the third conductive layer.

### BRIEF DESCRIPTION OF DRAWINGS

Aspects, features, and advantages in the example embodiments will be more clearly understood from the following detailed description, taken in combination with the accompanying drawings, in which:

FIG. 1 is a plan view illustrating a semiconductor device according to example embodiments of the present disclosure;

FIGS. 2A and 2B are cross-sectional views illustrating a semiconductor device according to example embodiments of the present disclosure;

FIGS. 3A and 3B are cross-sectional views illustrating a semiconductor device according to example embodiments of the present disclosure;

FIG. 4 is a cross-sectional view illustrating a semiconductor device according to example embodiments of the present disclosure;

FIGS. 5A and 5B are cross-sectional views illustrating a semiconductor device according to example embodiments of the present disclosure;

FIG. 6 is a cross-sectional view illustrating a semiconductor device according to example embodiments of the present disclosure;

FIG. 7 is a cross-sectional view illustrating a semiconductor device according to example embodiments of the present disclosure; and

FIGS. 8A to 8N are views illustrating processes of a method of manufacturing a semiconductor device in order according to example embodiments of the present disclosure.

### DETAILED DESCRIPTION

Hereinafter, embodiments of the present disclosure will be described as follows with reference to the accompanying drawings.

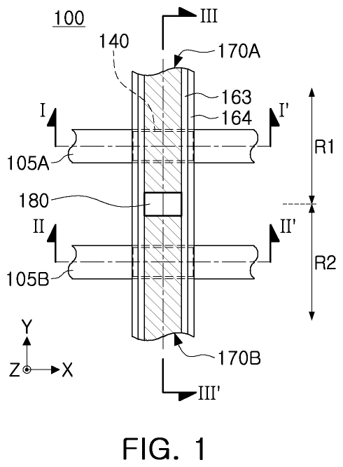

FIG. 1 is a plan view illustrating a semiconductor device according to example embodiments.

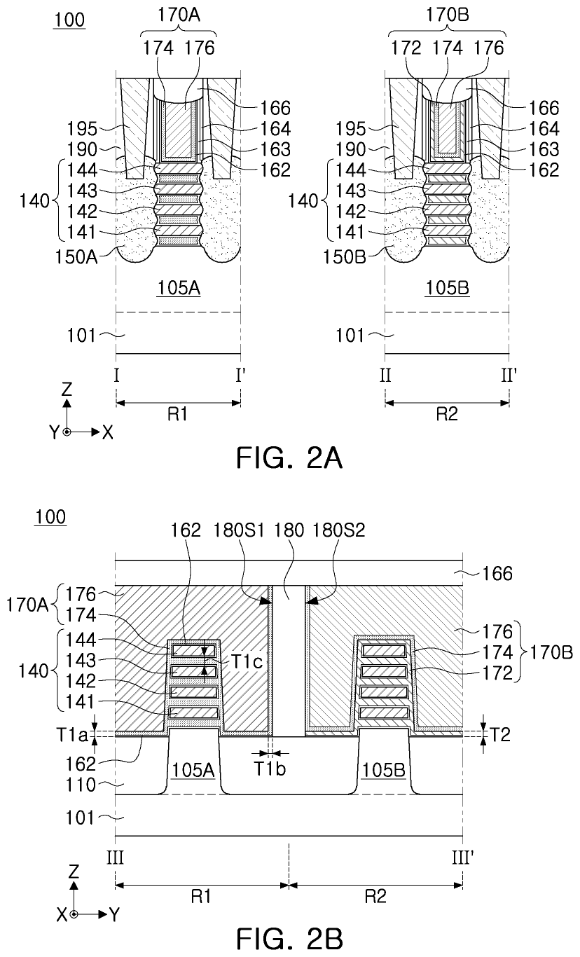

FIGS. 2A and 2B are cross-sectional views illustrating a semiconductor device according to example embodiments. FIG. 2A is a cross-sectional view taken along line I-I′ and II-II′ in FIG. 1, and FIG. 2B is a cross-sectional view taken along line III-III′ in FIG. 1. For ease of description, FIG. 1 illustrates only a portion of components of the semiconductor device.

Referring to FIGS. 1 to 2B, a semiconductor device 100 may include a substrate 101 having first and second regions R1 and R2, first and second active regions 105A and 105B on the substrate 101, channel structures 140 including first to fourth channel layers 141, 142, 143, and 144 vertically disposed and spaced apart from each other on the first and second active regions 105A and 105B, first gate electrode 170A extending lengthwise by intersecting or crossing the first active region 105A, a second gate electrode 170B extending lengthwise by intersecting or crossing the second active region 105B, a gate isolation layer 180 isolating the first gate electrode 170A and the second gate electrode 170B from each other, first and second source/drain regions 150A and 150B in contact with the channel structures 140, and contact plugs 195 electrically connected to or contacting the respective first and second source/drain regions 150A and 150B. The semiconductor device 100 may further include a device isolation layer 110, gate dielectric/insulating layers 162, first and second gate spacer layers 163 and 164, gate capping layers 166, and an interlayer insulating layer 190. As used herein, components described as being “electrically connected” are configured such that an electrical signal can be transferred from one component to the other (although such electrical signal may be attenuated in strength as it is transferred and may be selectively transferred). It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In the semiconductor device 100, each of the first and second active regions 105A and 105B may have a fin structure, and the first and second gate electrodes 170A and 170B may be disposed between the first and second active regions 105A and 105B and the channel structure 140, between the first to fourth channel layers 141, 142, 143, and 144 of the channel structure 140, and on the channel structure 140. Accordingly, the semiconductor device 100 may include transistors having a multi bridge channel FET (MBCFET™) structure and/or a gate-all-around type field effect transistor.

The substrate 101 may have an upper surface extending in the X-direction and the Y-direction. The substrate 101 may include a semiconductor material, such as a group IV semiconductor, a group III-V compound semiconductor, or a group II-VI compound semiconductor. For example, a group IV semiconductors may include or may be silicon, germanium, or silicon-germanium. The substrate 101 may be provided as a bulk wafer, an epitaxial layer, a silicon on insulator (SOI) layer, or a semiconductor on insulator (SeOI) layer. Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

The substrate 101 may include first and second regions R1 and R2, and the first and second regions R1 and R2 may be adjacent to each other. The first active region 105A, the first source/drain regions 150A, and the first gate electrode 170A may be disposed on the first region R1, and the second active region 105B, the second source/drain regions 150B, and the second gate electrode 170B may be disposed on the second region R2. For example, on the first region R1, a nFET may be disposed, and on the second region R2, a pFET may be disposed. In some example embodiments, on each of the first and second regions R1 and R2, transistors having the same conductivity type and different electrical properties may be disposed.

The first and second active regions 105A and 105B may be defined by the device isolation layer 110 and may extend in the first direction, for example, the X-direction. In example embodiments, the first and second active regions 105A and 105B may be described as a portion of the substrate 101. The first and second active regions 105A and 105B may partially protrude from the device isolation layer 110, such that upper surfaces of the first and second active regions 105A and 105B may be disposed on a level higher than a level of an upper/top surface of the device isolation layer 110. The first and second active regions 105A and 105B may be formed as a portion of the substrate 101 or may include an epitaxial layer grown from the substrate 101. On both sides of the first and second gate electrodes 170A and 170B, the first and second active regions 105A and 105B may be partially recessed and recess regions may be formed, and the first and second source/drain regions 150A and 150B may be disposed in the recess regions.

Each of the first and second active regions 105A and 105B may include well regions including impurities. For example, in the first active region 105A of the first region R1 in which the nFET is disposed, the well region may include P-type impurities such as boron (B), gallium (Ga), or aluminum (Al). In the second active region 105B of the second region R2 in which the pFET is disposed, the well region may include N-type impurities such as phosphorus (P), arsenic (As), or antimony (Sb). For example, the well region may be disposed at a predetermined depth from an upper surface of each of the first and second active regions 105A and 105B.

The device isolation layer 110 may define the first and second active regions 105A and 105B in the substrate 101. The device isolation layer 110 may be formed, for example, by a shallow trench isolation (STI) process. The device isolation layer 110 may expose upper surfaces of the first and second active regions 105A and 105B, and may partially expose an upper portion of each of active regions 105A and 105B. In some example embodiments, the device isolation layer 110 may have a curved/inclined upper surface having a level increasing in a direction approaching the first and second active regions 105A and 105B. The device isolation layer 110 may be formed of an insulating material. The device isolation layer 110 may be formed of, for example, oxide, nitride, or a combination thereof.

The channel structures 140 may include first to fourth channel layers 141, 142, 143, and 144 spaced apart from each other in a direction perpendicular to upper surfaces of the first and second active regions 105A and 105B, for example, in the Z-direction, on the first and second active regions 105A and 105B, respectively. In example embodiments, the channel structures 140 may include a plurality of channel layers, e.g., two or more channel layers. The first to fourth channel layers 141, 142, 143, and 144 may be electrically connected to (e.g., contact) the first and second source/drain regions 150A and 150B, and may be spaced apart from upper surfaces of the first and second active regions 105A and 105B. The first to fourth channel layers 141, 142, 143, and 144 may have a width the same as or similar to those of the first and second active regions 105A and 105B in the Y-direction, and may have a width the same as or similar to that of a gate structure including the first and second gate electrodes 170A and 170B, the gate dielectric/insulating layer 162, the first and second gate spacer layers 163 and 164, and the gate capping layer 166 in the X-direction.

The first to fourth channel layers 141, 142, 143, and 144 may be formed of a semiconductor material, and may include, for example, at least one of silicon (Si), silicon germanium (SiGe), and germanium (Ge). For example, the first to fourth channel layers 141, 142, 143, and 144 may be formed of the same material as that of the substrate 101. In example embodiments, the first to fourth channel layers 141, 142, 143, and 144 may include an impurity region disposed in a region adjacent to the source/drain regions 150. The number of the channel layers 141, 142, 143, and 144 of each of the channel structures 140 and the shape thereof may vary in example embodiments.

The first and second source/drain regions 150A and 150B may be disposed on the first and second active regions 105A and 105B on both sides of the first and second gate electrodes 170A and 170B and the channel structures 140, respectively. The first source/drain regions 150A may be disposed on the first active regions 105A on both sides of the first gate electrode 170A, and the second source/drain regions 150B may be disposed on the second active regions 105B on both sides of the second gate electrode 170B.

The first and second source/drain regions 150A and 150B may be disposed in recess regions partially recessed into an upper portion of the first and second active regions 105A and 105B. The first and second source/drain regions 150A and 150B may be in contact with the first to fourth channel layers 141, 142, 143, and 144 of the channel structures 140, and may be disposed to cover side surfaces of each of the first to fourth channel layers 141, 142, 143, and 144. The upper surfaces of the first and second source/drain regions 150A and 150B may be disposed on a level the same as or similar to a level of lower surfaces of uppermost portions (e.g., portions disposed above the uppermost channel layer 144) of the first and second gate electrodes 170A and 170B, and the level may vary in example embodiments. For example, the upper surfaces of the first and second source/drain regions 150A and 150B may be higher than an upper surface of the uppermost channel layer 144. In some example embodiments, the first and second source/drain regions 150A and 150B may be directly connected to or merged with each other on two or more adjacent first and second active regions 105A and 105B in the Y-direction, and may form a combined one of the first and second source/drain regions 150A and 150B.

The first and second source/drain regions 150A and 150B may include impurities of different conductivity types. For example, the first source/drain regions 150A may include N-type impurities, and the second source/drain regions 150B may include P-type impurities, but the inventive concept is not limited thereto.

The gate structure may include first and second gate electrodes 170A and 170B, a gate dielectric/insulating layer 162, first and second gate spacer layers 163 and 164, and a gate capping layer 166.

The first and second gate electrodes 170A and 170B may intersect with and/or cross the first and second active regions 105A and 105B and the channel structures 140 on the first and second active regions 105A and 105B and the channel structures 140 and may extend in the second direction, for example, the Y-direction. Physical channel regions of transistors may be formed in the first and second active regions 105A and 105B and/or the channel structures 140 intersecting/crossing the first and second gate electrodes 170A and 170B. The first and second gate electrodes 170A and 170B may fill a space between the first and fourth channel layers 141, 142, 143, and 144 on the first and second active regions 105A and 105B, and may extend onto the channel structures 140. The first and second gate electrodes 170A and 170B may be spaced apart from the first to fourth channel layers 141, 142, 143, and 144 by the gate dielectric/insulating layer 162.

The first and second gate electrodes 170A and 170B may be disposed linearly, in one direction, for example, in the Y-direction. For example, the first and second gate electrodes 170A and 170B may extend linearly in a horizontal direction (e.g., in a straight line shape in a plan view). The first gate electrode 170A and second gate electrode 170B may be disposed on the first and second regions R1 and R2, respectively, with the gate isolation layer 180 therebetween. The first gate electrode 170A may include second and third conductive layers 174 and 176 stacked in order, and the second gate electrode 170B may include the first to third conductive layers 172, 174, and 176 stacked in order. The first and second gate electrodes 170A and 170B may form the nFET and the pFET, respectively. Alternatively, the first and second gate electrodes 170A and 170B may form nFETs having different operating voltages, or pFETs having different operating voltages.

On the first region R1, the second conductive layer 174 may be disposed on the gate dielectric/insulating layers 162. The second conductive layer 174 may fill a space between the first to fourth channel layers 141, 142, 143, and 144, may extend along side surfaces and an upper surface of the entire channel structure 140, and may extend along an upper surface of the device isolation layer 110 and the first side surface 180S1 of the gate isolation layer 180. The second conductive layer 174 may only extend to an upper end of the first side surface 180S1. The third conductive layer 176 may be disposed on the second conductive layer 174 and may fill a space on the second conductive layer 174, e.g., in a cross-sectional view cut along a plane perpendicular to the X-direction as shown in FIG. 2B.

The second conductive layer 174 may have substantially the same thickness in regions other than a region between the first to fourth channel layers 141, 142, 143, and 144. For example, in the second conductive layer 174, a first thickness T1a on an upper surface of the device isolation layer 110 may be substantially equal to a second thickness T1b on a first side surface 180S1 of the gate isolation layer 180. The first and second thicknesses T1a and T1b may be substantially the same as a thickness on an upper surface of the fourth channel layer 144. The second conductive layer 174 may have a third thickness T1c between the first to fourth channel layers 141, 142, 143, and 144, and the third thickness T1c may be equal to or greater than the first and second thicknesses T1a and T1b. The third conductive layer 176 may have a thickness greater than that of the second conductive layer 174.

On the second region R2, the first conductive layer 172 may be disposed on the gate dielectric layers 162. The first conductive layer 172 may fill a space between the first to fourth channel layers 141, 142, 143, and 144, may extend along side surfaces and an upper surface of the entire channel structure 140, may extend along an upper surface of the device isolation layer 110 and may be in contact with the second side surface 180S2 in a lower portion of the gate isolation layer 180. The first conductive layer 172 may have substantially the same fourth thickness T2 in regions other than a region between the first to fourth channel layers 141, 142, 143, and 144. The fourth thickness T2 may be the same as or different from the first thickness T1a of the second conductive layer 174.

The second conductive layer 174 may be disposed on the first conductive layer 172 and may conformally extend along the entire channel structure 140 and the second side surface 180S2 of the gate isolation layer 180. The second conductive layer 174 may extend to substantially uniform thickness and may have a thickness substantially the same as the first and second thicknesses T1a and T1b on the first region R1. The second conductive layer 174 may extend to an upper end of the second side surface 180S2. The third conductive layer 176 may be disposed on the second conductive layer 174 and may fill a space in the second conductive layer 174 in a cross-sectional surface taken in the X-direction.

The first and second gate electrodes 170A and 170B may be electrically isolated from each other by the gate isolation layer 180. The first and second gate electrodes 170A and 170B may have an asymmetric internal structure with respect to the gate isolation layer 180, for example, a stack structure of different conductive layers.

The first and second gate electrodes 170A and 170B may include a conductive material, for example, a metal nitride such as titanium nitride (TiN), tantalum nitride (TaN), or tungsten nitride (WN), and/or a metal material such as aluminum (Al), tungsten (W), or molybdenum (Mo), or semiconductor materials such as doped polysilicon. The first conductive layer 172 may include a material different from those of the second and third conductive layers 174 and 176, and the second and third conductive layers 174 and 176 may include the same material or different materials. Even when the second and third conductive layers 174 and 176 include the same material, the second and third conductive layers 174 and 176 may be formed in different processes, and an interfacial surface therebetween may be distinct.

For example, the first to third conductive layers 172, 174, and 176 may be metal layers. In an example embodiment, the second conductive layer 174 may have a work function equal to or smaller than that of the first conductive layer 172. For example, the first and second conductive layers 172 and 174 may be metal layers for adjusting the work function, and the first conductive layer 172 may include P-type metal and the second conductive layer 174 may include N-type metal. For example, the first conductive layer 172 may include at least one of TiAlN and TiN, and the second conductive layer 174 may include at least one of TiAlC and TiN, but the inventive concept is not limited thereto.

The gate dielectric layers 162 may be disposed between the first and second active regions 105A and 105B and the first and second gate electrodes 170A and 170B and between the channel structures 140 and the first and second gate electrodes 170A and 170B and may be disposed to cover at least a portion of surfaces of the first and second gate electrodes 170A and 170B. For example, the gate dielectric layers 162 may be disposed to surround the entirety of surfaces other than uppermost surfaces of the first and second gate electrodes 170A and 170B. The gate dielectric layers 162 may extend to a region between the first and second gate electrodes 170A and 170B and the first gate spacer layers 163, but the inventive concept is not limited thereto.

The gate dielectric layers 162 may include oxide, nitride, or a high-κ material. The high-κ material may refer to a dielectric material having a dielectric constant higher than that of a silicon dioxide (SiO₂). The high-κ material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In some example embodiments, the gate dielectric layer 162 may be formed as a multilayer film.

The first and second gate spacer layers 163 and 164 may be disposed on both side surfaces of each of the first and second gate electrodes 170A and 170B. The first and second gate spacer layers 163 and 164 may insulate the first and second source/drain regions 150A and 150B and the first and second gate electrodes 170A and 170B from each other. The first and second gate spacer layers 163 and 164 may be stacked and may form a multilayer structure. However, in some example embodiments, the gate spacer layer may be configured as a single layer. The first and second gate spacer layers 163 and 164 may include at least one of oxide, nitride, and oxynitride, for example, a low dielectric constant film.

The gate capping layers 166 may be disposed on the first and second gate electrodes 170A and 170B, respectively. The gate capping layers 166 may include at least one of oxide, nitride, and oxynitride.

The gate isolation layer 180 may be disposed between the first gate electrode 170A and the second gate electrode 170B to isolate the first and second gate electrodes 170A and 170B from each other. A lower surface of the gate isolation layer 180 may be in contact with the device isolation layer 110 and may be disposed on a level lower than a level of upper surfaces of the first and second active regions 105A and 105B. An upper surface of the gate isolation layer 180 may be coplanar with upper surfaces of the first and second gate electrodes 170A and 170B. An upper surface of the gate isolation layer 180 may be exposed from the second conductive layer 174 and may be covered by the gate capping layer 166. However, in some example embodiments, an upper surface of the gate isolation layer 180 may be covered by an insulating material of another layer, such as the interlayer insulating layer 190. Side surfaces of the gate isolation layer 180 may be perpendicular or inclined to an upper surface of the substrate 101. The gate isolation layer 180 may be disposed between a pair of first gate spacer layers 163 in the X-direction as illustrated in FIG. 1. However, in some example embodiments, the gate isolation layer 180 may penetrate at least a portion of the first and second gate spacer layers 163 and 164 and may have a shape expanding in the X-direction.

In the gate isolation layer 180, among the first and second side surfaces 180S1 and 180S2 in the Y-direction, the first side surface 180S1 may correspond to the left surface in FIG. 2B and may be entirely covered by the gate dielectric layer 162 and the second conductive layer 174. The first side surface 180S1 may be in contact with the gate dielectric layer 162 in a lower portion, and may be in contact with the second conductive layer 174 in other regions.

The second side surface 180S2 may correspond to the right surface in FIG. 2B and may be in contact with the gate dielectric layer 162 and the first and second conductive layers 172, 174. The second side surface 180S2 may be in contact with the gate dielectric layer 162 in a lower portion, may be in contact with the first conductive layer 172 by a length corresponding to a thickness of the first conductive layer 172 on the gate dielectric layer 162, and the other regions may be covered with the second conductive layer 174. A second height of a second portion of the second side surface 180S2 which is in contact with the second conductive layer 174 may be higher/greater than a first height of a first portion of the second side surface 180S2 which is in contact with the first conductive layer 172, for example, the second height may be 10 times the first height or more, for example, 30 times the first height or more and 50 times the first height or less. For example, the first height may be measured from a bottom to a top of the first portion, and the second height may be measured from a bottom to a top of the second portion.

The gate isolation layer 180 may include an insulating material. For example, the gate isolation layer 180 may include at least one of silicon oxide, silicon nitride, silicon oxynitride, and silicon carbide. In the example embodiment, the gate isolation layer 180 may be formed as a single insulating layer.

The interlayer insulating layer 190 may cover the first and second source/drain regions 150A and 150B. The interlayer insulating layer 190 may include at least one of oxide, nitride, and oxynitride, and may include, for example, a low dielectric constant material. In example embodiments, the interlayer insulating layer 190 may include a plurality of insulating layers.

The contact plugs 195 may penetrate the interlayer insulating layer 190, may be electrically connected to and/or contact the first and second source/drain regions 150A and 150B, and may apply an electrical signal to the first and second source/drain regions 150A and 150B. The contact plugs 195 may have an inclined side surface of which a width of a lower portion is narrower than a width of an upper portion depending on an aspect ratio, but the inventive concept is not limited thereto. For example, the contact plugs 195 may extend to a region below a lower surface of the fourth channel layer 144 or an uppermost channel layer of the channel structure 140, but the inventive concept is not limited thereto. In some example embodiments, the contact plugs 195 may be disposed to be in contact with upper surfaces of the first and second source/drain regions 150A and 150B, rather than being recessed into or penetrating the first and second source/drain regions 150A and 150B.

Each of the contact plugs 195 may include a metal-semiconductor compound layer, for example, a metal silicide layer, disposed on a lower end including a lower surface, and may further include a barrier layer forming side surfaces of the contact plug 195 and extending to an upper surface of the metal-semiconductor compound layer. For example, the barrier layer may include a metal nitride such as titanium nitride (TiN), tantalum nitride (TaN), or tungsten nitride (WN). The contact plugs 195 may include a metal material such as aluminum (Al), tungsten (W), or molybdenum (Mo). In an illustrative example embodiment, the number of the conductive layers included in the contact plugs 195 and the arrangement shape thereof may vary.

An interconnection structure such as a contact plug may be further disposed on the first and second gate electrodes 170A and 170B, and an interconnection structure such as an interconnection line electrically connected to (e.g., contacting) the contact plugs 195 may be further disposed on the contact plugs 195.

In the description of the example embodiment below, descriptions overlapping the description described with reference to FIGS. 1 to 2B will not be provided.

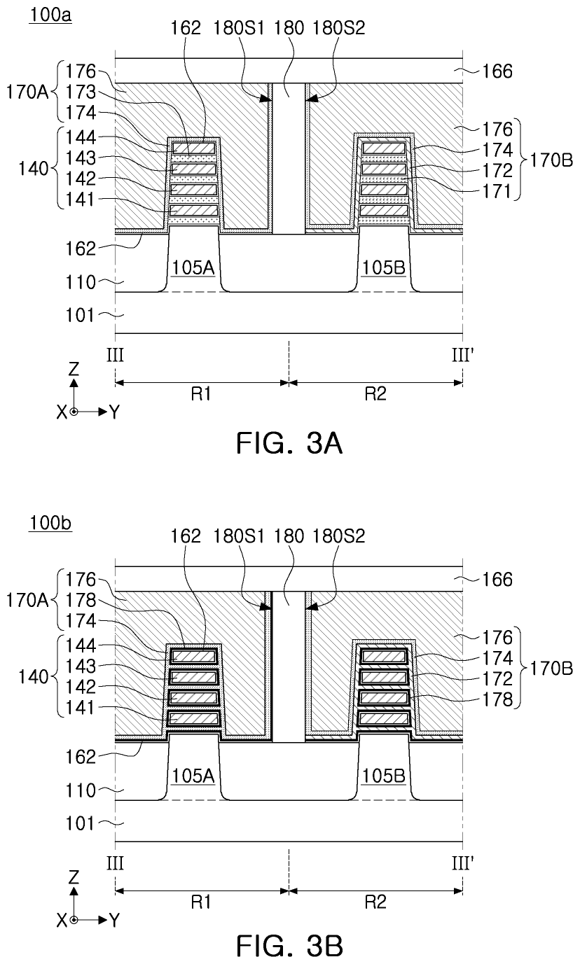

FIGS. 3A and 3B are cross-sectional views illustrating a semiconductor device according to example embodiments, illustrating a region corresponding to FIG. 2B.

Referring to FIG. 3A, in a semiconductor device 100a, a second gate electrode 170B may further include a first lower conductive layer 171, and a first gate electrode 170A may further include a second lower conductive layer 173.

The first and second lower conductive layers 171 and 173 may fill a space between the first to fourth channel layers 141, 142, 143, and 144 and may be disposed only between the first to fourth channel layers 141, 142, 143, and 144. In the example embodiment, the first lower conductive layer 171 may include a material different from that of the first conductive layer 172, and the second lower conductive layer 173 may include a material different from that of the second conductive layer 174. The first and second lower conductive layers 171 and 173 may include, for example, a metal material, but the inventive concept is not limited thereto.

Referring to FIG. 3B, in a semiconductor device 100b, each of first and second gate electrodes 170A and 170B may further include a barrier conductive layer 178.

The barrier conductive layer 178 may be disposed on each of the gate dielectric layers 162. Between the first to fourth channel layers 141, 142, 143, and 144, the barrier conductive layer 178 may cover the gate dielectric layers 162 and may be disposed to not fill a space between the first to fourth channel layers 141, 142, 143, and 144. On upper surfaces of the first and second active regions 105A and 105B, the barrier conductive layer 178 may cover the gate dielectric layers 162 and may extend in the Y-direction.

On the first region R1, the barrier conductive layer 178 may extend to cover a first side surface 180S1 of the gate isolation layer 180. However, in some example embodiments, the barrier conductive layer 178 may be in contact with a first side surface 180S1 in a lower portion of the gate isolation layer 180 and may not extend to an upper portion along the first side surface 180S1. On the second region R2, the barrier conductive layer 178 may be in contact with a second side surface 180S2 of the gate isolation layer 180 and may not extend to an upper portion along the second side surface 180S2. The barrier conductive layer 178 may include a material different from those of the first to third conductive layers 172, 174, and 176, for example, metal nitride, but the inventive concept is not limited thereto.

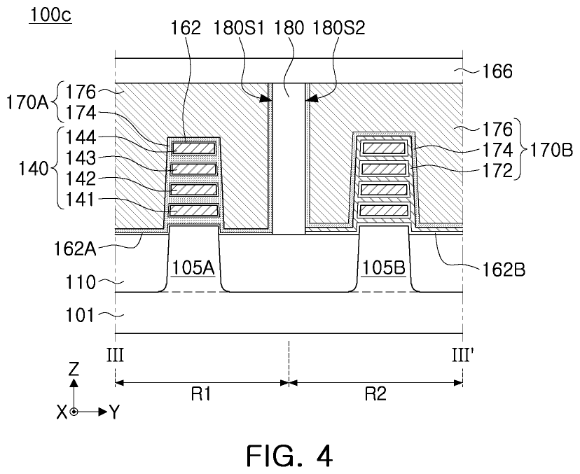

FIG. 4 is a cross-sectional view illustrating a semiconductor device according to example embodiments, illustrating a region corresponding to FIG. 2B.

Referring to FIG. 4, a semiconductor device 100c may include first and second gate dielectric layers 162A and 162B.

The first gate dielectric layers 162A may be disposed on a first region R1, and the second gate dielectric layers 162B may be disposed on a second region R2. At least one of a material and a thickness of each of the first gate dielectric layers 162A may be different from those of the second gate dielectric layers 162B. The first and second gate dielectric layers 162A and 162B may also be combined in another example embodiment.

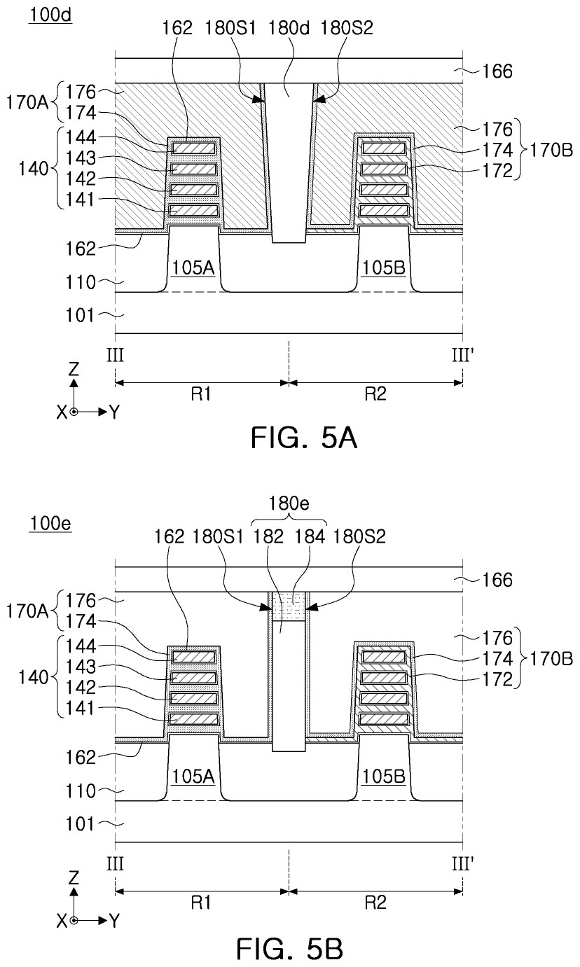

FIGS. 5A and 5B are cross-sectional views illustrating a semiconductor device according to example embodiments, illustrating a region corresponding to FIG. 2B.

Referring to FIG. 5A, in a semiconductor device 100d, a gate isolation layer 180d may have inclined first and second side surfaces 180S1 and 180S2. Accordingly, a horizontal distance between the first and second side surfaces 180S1 and 180S2 on an upper portion of the gate isolation layer 180d may be greater than a horizontal distance between the first and second side surfaces 180S1 and 180S2 on a lower portion of the gate isolation layer 180d. The gate isolation layer 180d may have a width in a horizontal direction (e.g., Y direction) decreases in a direction approaching the substrate 101. Also, in the example embodiment, a lower end of the isolation layer 180d may be disposed in the device isolation layer 110 by partially recessing or penetrating the device isolation layer 110. A slope of the gate isolation layer 180d and a position of the lower end may be independently applied to other example embodiments.

Referring to FIG. 5B, in a semiconductor device 100e, a gate isolation layer 180e may include first and second isolation layers 182 and 184.

The first isolation layer 182 may be disposed on a device isolation layer 110, and the second isolation layer 184 may be disposed on the first isolation layer 182. A height of the second isolation layer 184 may be lower than a height of the first isolation layer 182. However, in the example embodiment, the number of insulating layers forming the gate isolation layer 180e and relative levels thereof may vary.

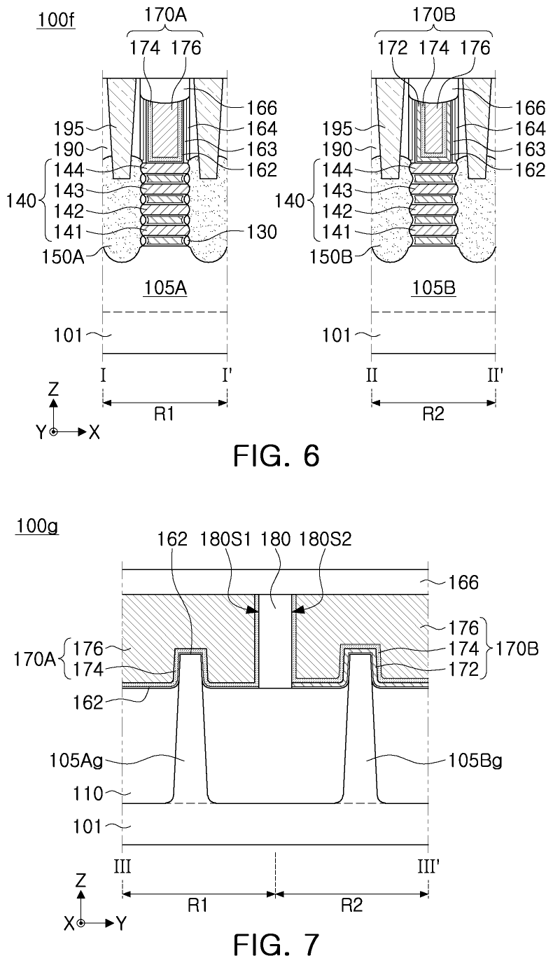

FIG. 6 is a cross-sectional view illustrating a semiconductor device according to example embodiments, illustrating a region corresponding to FIG. 2A.

Referring to FIG. 6, a semiconductor device 100f may further include internal spacer layers 130 disposed between gate dielectric layers 162 and first source/drain regions 150A on a first region R1.

The internal spacer layers 130 may be disposed to be parallel to a first gate electrode 170A between first to fourth channel layers 141, 142, 143, and 144 stacked in the Z-direction. For example, the internal spacer layers 130 may extend lengthwise in a horizontal direction (Y direction). The first gate electrode 170A may be stably spaced apart from the first source/drain regions 150A by the internal spacer layers 130 and may be electrically isolated therefrom. Side surfaces of the internal spacer layers 130 facing the first gate electrode 170A may have convex shapes, and side surfaces of the first gate electrode 170A facing the internal spacer layers may have inwardly curved round shapes, e.g., concave shapes, but the inventive concept is not limited thereto. The internal spacer layers 130 may include at least one of oxide, nitride, and oxynitride, and may be, for example, a low dielectric constant layer. In some example embodiments, internal spacer layers 130 may be further disposed in a second region R2 in the same way as in the first region R1.

FIG. 7 is a cross-sectional view illustrating a semiconductor device according to example embodiments, illustrating a region corresponding to FIG. 2B.

Referring to FIG. 7, a semiconductor device 100g may not include the channel structures 140, differently from the example embodiments in FIGS. 1 to 2B, and accordingly, the arrangement of the first and second gate electrodes 170A and 170B may be different from the aforementioned example embodiments. The semiconductor device 100g may include transistors having a FinFET structure not including a separate channel layer.

In the semiconductor device 100g, a channel region of transistors may be limitedly located in first and second active regions 105Ag and 105Bg having a fin structure as an active structure. Also, channel layers may not be interposed in the first and second gate electrodes 170A and 170B. Regarding the gate isolation layer 180, the above description for the gate isolating layer 180 of the example embodiment of FIGS. 1 to 2B may also be applied to the gate isolation layer 180 of the semiconductor device 100g. The semiconductor device 100g may be disposed in a region of a semiconductor device of another example embodiment.

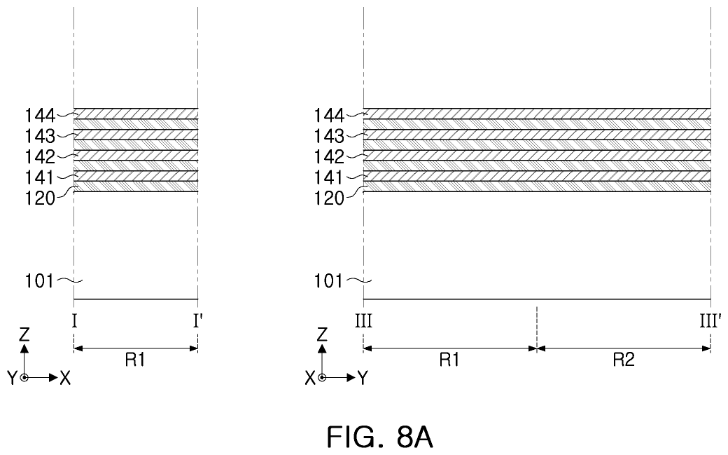

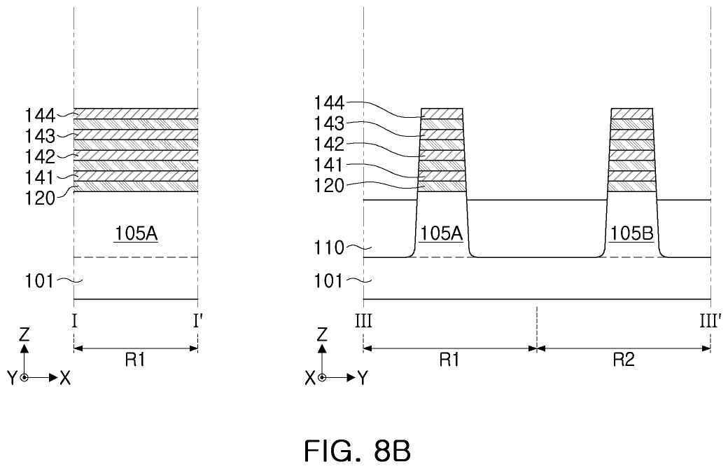

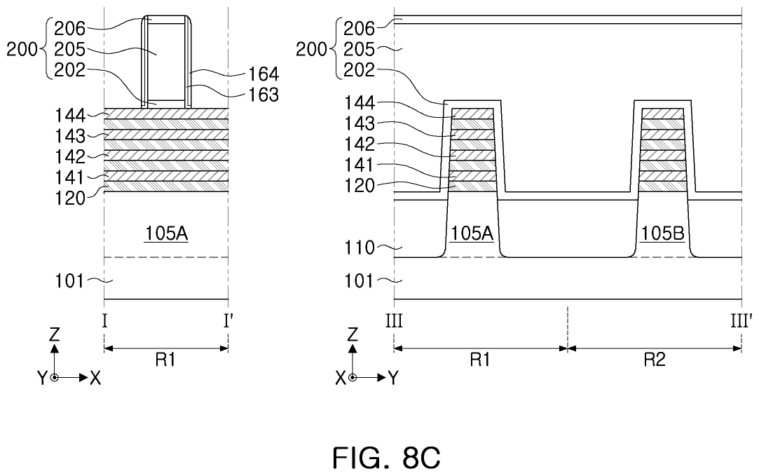

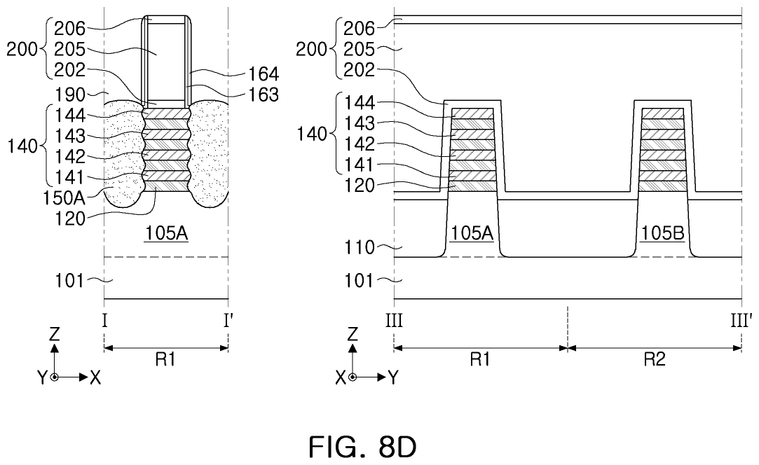

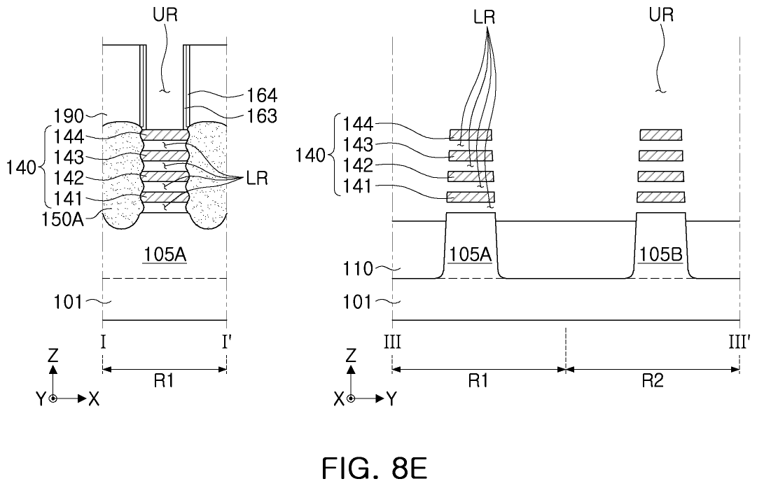

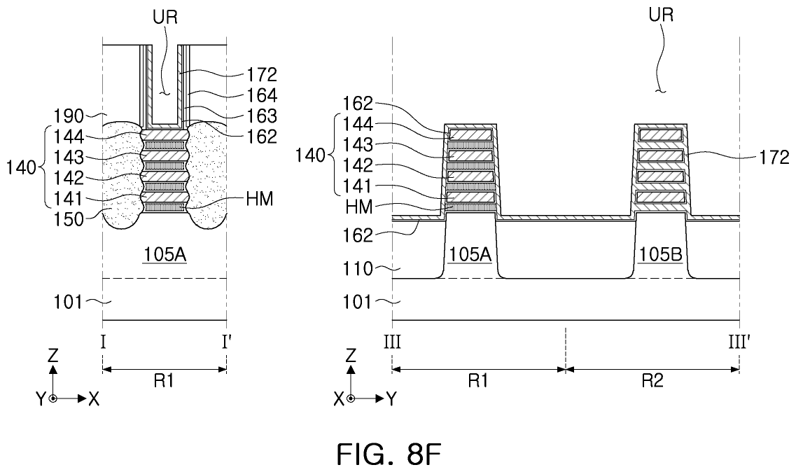

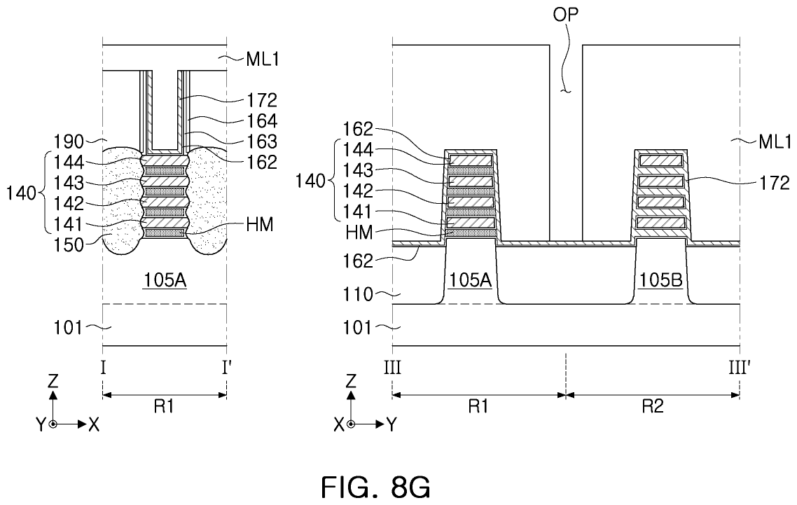

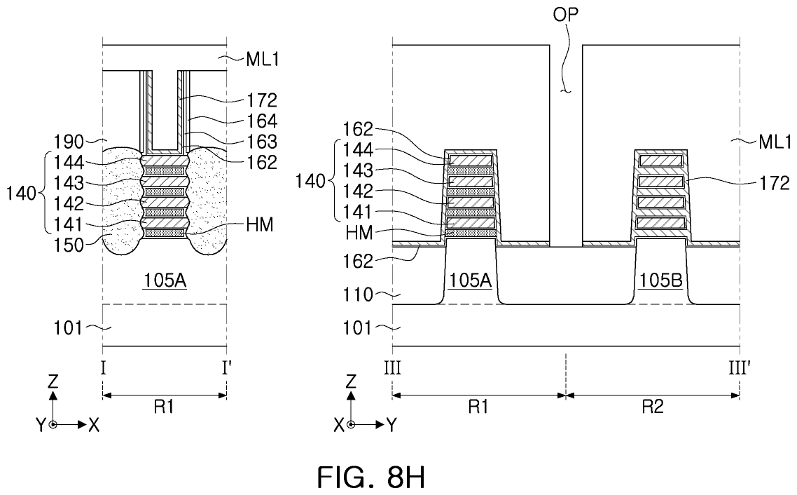

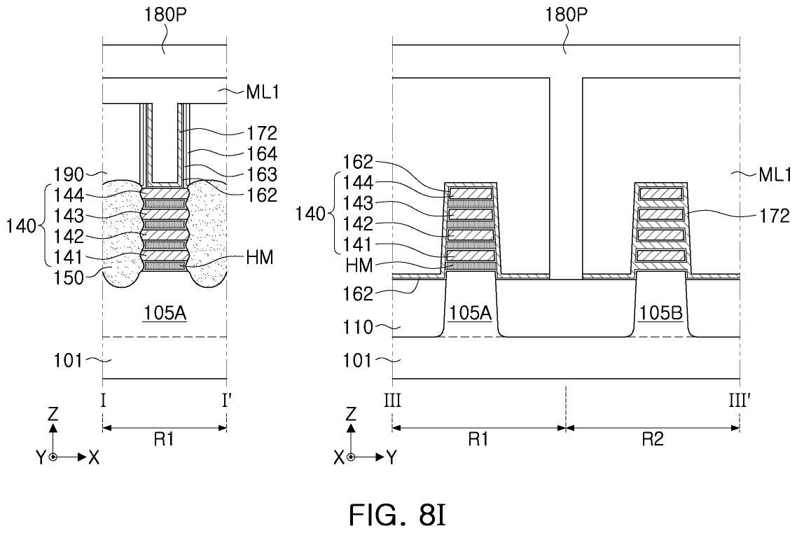

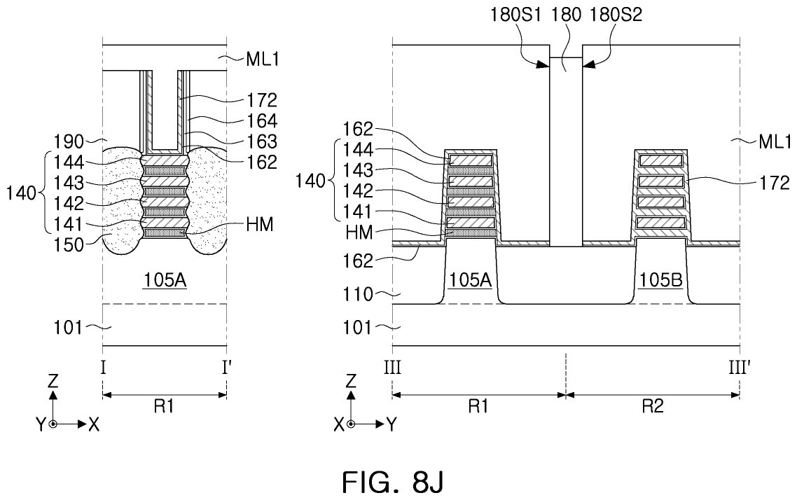

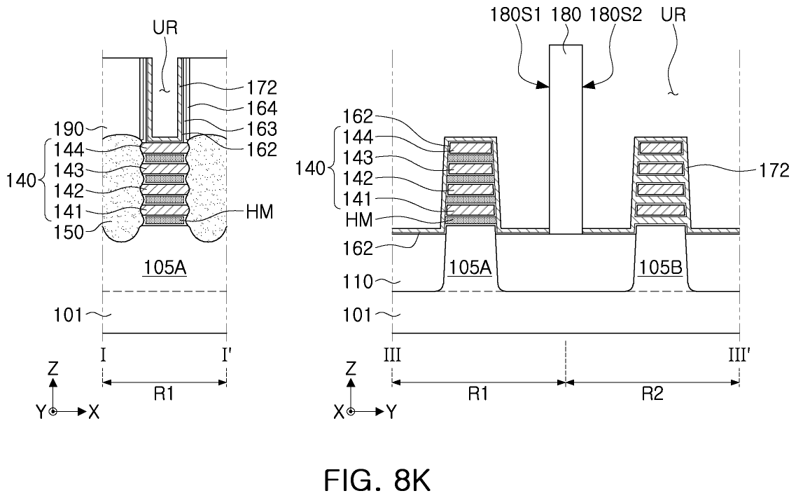

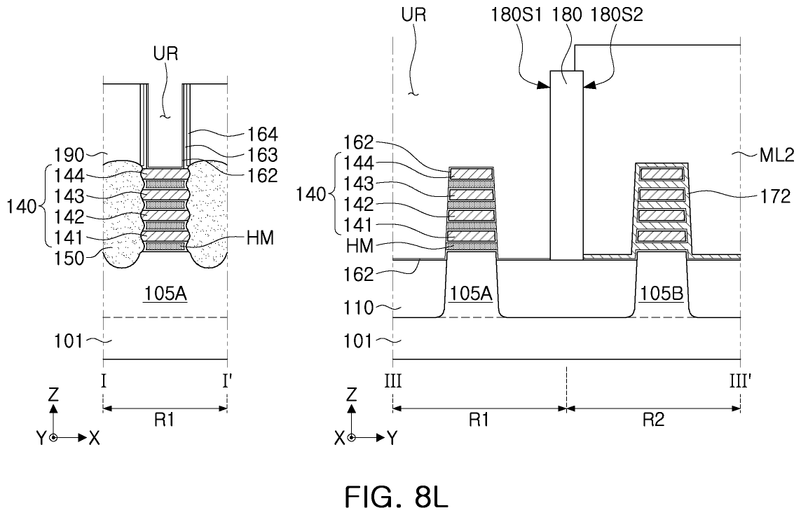

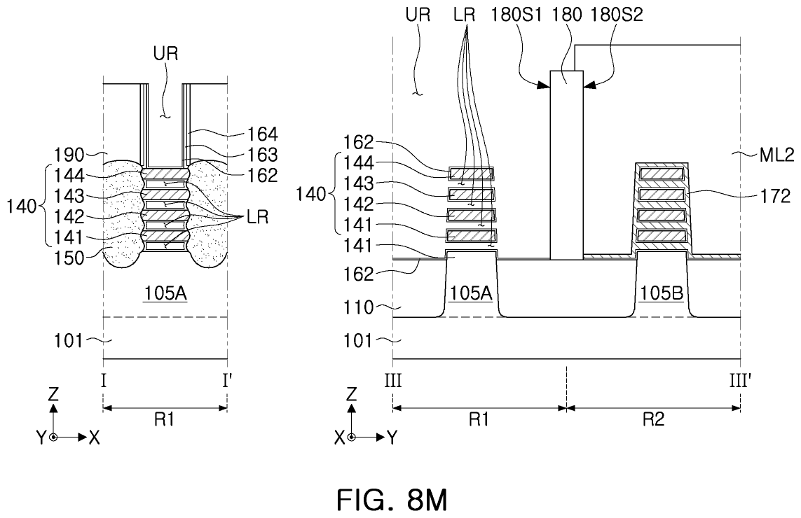

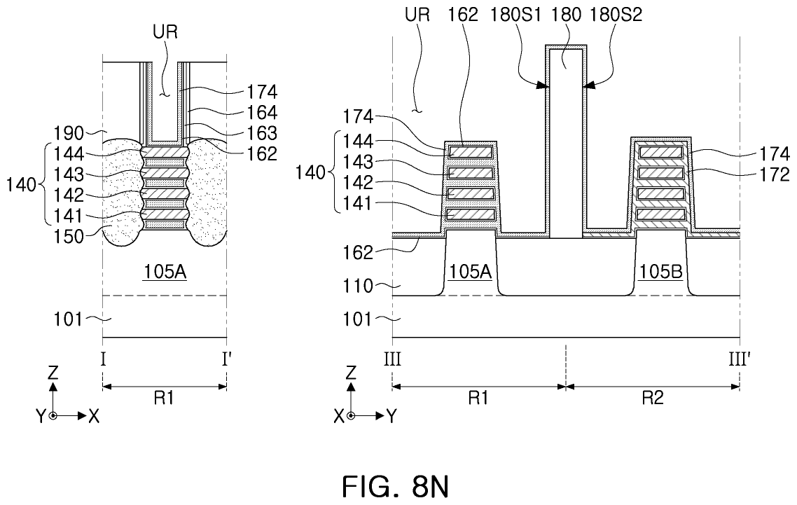

FIGS. 8A to 8N are views illustrating processes of a method of manufacturing a semiconductor device in order according to example embodiments. FIGS. 8A to 8N illustrate an example embodiment of a method of manufacturing the semiconductor device in FIGS. 1 to 2B. FIGS. 8A to 8N illustrate cross-sectional views taken along lines I-I′ and III-III′ in FIG. 1.

Referring to FIG. 8A, sacrificial layers 120 and first to fourth channel layers 141, 142, 143, and 144 may be alternately stacked on a substrate 101.

Sacrificial layers 120 may be replaced with gate dielectric layers 162 and first and second gate electrodes 170A and 170B as illustrated in FIGS. 2A and 2B through a subsequent process. The sacrificial layers 120 may be formed of a material having etch selectivity for the first to fourth channel layers 141, 142, 143, and 144. The first to fourth channel layers 141, 142, 143, and 144 may include a material different from that of the sacrificial layers 120. The sacrificial layers 120 and the first to fourth channel layers 141, 142, 143, and 144 may include, for example, a semiconductor material including at least one of silicon (Si), silicon germanium (SiGe), and germanium (Ge), and may include different materials and may or may not include impurities. For example, the sacrificial layers 120 may include silicon germanium (SiGe), and the first to fourth channel layers 141, 142, 143, and 144 may include silicon (Si).

The sacrificial layers 120 and the first to fourth channel layers 141, 142, 143, and 144 may be formed by performing an epitaxial growth process from the substrate 101. The number of the channel layers 141, 142, 143, and 144, alternately stacked with the sacrificial layers 120, may vary in example embodiments.

Referring to FIG. 8B, active structures may be formed by removing a portion of the sacrificial layers 120, the first to fourth channel layers 141, 142, 143, and 144, and the substrate 101 and a device isolation layer 110 may be formed.

The active structures may include the sacrificial layers 120 and the first to fourth channel layers 141, 142, 143, and 144, alternately stacked with each other, and may further include first and second active regions 105A and 105B formed by removing a portion of the substrate 101 and protruding from the substrate 101. The active structures may be formed in a line shape extending lengthwise in a horizontal direction, for example, the X-direction, and may be spaced apart from each other in the Y-direction. The first and second active regions 105A and 105B may include the same or different impurities, and the impurities may be doped in the substrate 101 before the sacrificial layers 120 and the first to fourth channel layers 141, 142, 143, and 144 are formed.

In a region from which a portion of the substrate 101 has been removed, an insulating material may be filled, and a portion of the insulating material may be removed such that the first and second active regions 105A and 105B protrude from a top surface of the insulating material layer, thereby forming a device isolation layer 110. An upper surface of the device isolation layer 110 may be formed on a level lower than a level of an upper surface of the first and second active regions 105A and 105B.

Referring to FIG. 8C, a sacrificial gate structure 200 and first and second gate spacer layers 163 and 164 may be formed on the active structure.

The sacrificial gate structure 200 may be a sacrificial structure formed in a region in which the gate dielectric layers 162 and the first and second gate electrodes 170A and 170B are disposed on the channel structures 140 through a subsequent process, as illustrated in FIGS. 2A and 2B. The sacrificial gate structure 200 may have a line shape intersecting/crossing the active structures and extending lengthwise in a horizontal direction. The sacrificial gate structure 200 may longitudinally extend, for example, in the Y-direction.

The sacrificial gate structure 200 may include first and second sacrificial gate layers 202 and 205 and a mask pattern layer 206 stacked in order. The first and second sacrificial gate layers 202 and 205 may be patterned using the mask pattern layer 206. The first and second sacrificial gate layers 202 and 205 may be an insulating layer and a conductive layer, respectively, but the inventive concept is not limited thereto, and the first and second sacrificial gate layers 202 and 205 may be configured as an integrated layer, e.g., as one body without a boundary between the first and second sacrificial gate layers 202 and 205. For example, the first sacrificial gate layer 202 may include silicon oxide, and the second sacrificial gate layer 205 may include polysilicon. The mask pattern layer 206 may include silicon oxide and/or silicon nitride.

The first and second gate spacer layers 163 and 164 may be formed in order on both side walls of the sacrificial gate structure 200. The first and second gate spacer layers 163 and 164 may be formed of a low-κ material, and each of the first and second gate spacer layers 163 and 164 may include, for example, at least one of SiO, SiN, SiCN, SiOC, SiON, and SiOCN.

Referring to FIG. 8D, a portion of the sacrificial layers 120 and the first to fourth channel layers 141, 142, 143, and 144 exposed by the sacrificial gate structure 200 may be removed, and first and second source/drain regions 150A and 150B may be formed.

First, using the sacrificial gate structure 200 and the first and second gate spacer layers 163 and 164 as a mask, recess regions may be formed by removing a portion of the exposed sacrificial layers 120 and the first to fourth channel layers 141, 142, 143, and 144. Accordingly, the first to fourth channel layers 141, 142, 143, and 144 may form channel structures 140 having a limited length in the X-direction.

Thereafter, the first and second source/drain regions 150A and 150B may be formed by growing from side surfaces of the first and second active regions 105A and 105B and the channel structures 140, for example, by a selective epitaxial growth process. The first and second source/drain regions 150A and 150B may include impurities by in-situ doping and may include a plurality of layers having different doping elements and/or doping concentrations.

Referring to FIG. 8E, the interlayer insulating layer 190 may be formed, and the sacrificial layers 120 and the sacrificial gate structure 200 may be removed.

The interlayer insulating layer 190 may be formed by forming an insulating film covering the sacrificial gate structure 200 and the first and second source/drain regions 150A and 150B and performing a planarization process.

The sacrificial layers 120 and the sacrificial gate structure 200 may be selectively removed with respect to the first and second gate spacer layers 163 and 164, the interlayer insulating layer 190, and the channel structures 140. First, an upper portion gap region UR may be formed by removing the sacrificial gate structure 200, and lower gap regions LR may be formed by removing the sacrificial layers 120 exposed through the upper portion gap region UR. For example, when the sacrificial layers 120 include silicon germanium (SiGe) and the channel structures 140 include silicon (Si), the sacrificial layers 120 may be selectively removed by performing a wet etching process.

Referring to FIG. 8F, gate dielectric layers 162 may be formed, a sacrificial layer HM may be formed on the first region R1, and the first conductive layer 172 may be formed.

The gate dielectric layers 162 may be formed to conformally cover internal surfaces of the upper portion gap region UR and the lower gap regions LR on the first and second regions R1 and R2.

The sacrificial layer HM may be formed only on the first region R1, may be formed to completely fill the lower gap regions LR, and may not be formed in the upper portion gap region UR. For example, the sacrificial layer HM may be formed on the entire first and second regions R1 and R2, and may be partially removed to remain only between the first to fourth channel layers 141, 142, 143, and 144 of the first region R1, but the process of forming the sacrificial layer HM is not limited thereof. The sacrificial layer HM may include a material easily and selectively removed by a wet etching process during a subsequent process. The sacrificial layer HM may include a hard mask material and may include a material different from those of the gate dielectric layers 162, the first conductive layer 172, and the gate isolation layer 180 (see FIG. 2B).

The first conductive layer 172 may be formed on the entire first and second regions R1 and R2. The first conductive layer 172 may be formed to conformally cover the channel structure 140 on the first region R1, may fill a space between the first to fourth channel layers 141, 142, 143, and 144 and may conformally cover the channel structure 140 on the second region R2. For example, a portion of the first conductive layer 172 may be preferentially formed to fill a space between the first and fourth channel layers 141, 142, 143, and 144 on the second region R2, and the first conductive layer 172 may be further formed on the entire first and second regions R1 and R2.

Referring to FIG. 8G, a first mask layer ML1 may be formed.

The first mask layer ML1 may be patterned to have an opening OP exposing regions corresponding to the gate isolation layer 180 (see FIG. 2B). The opening OP may be formed on a boundary between a first region R1 and a second region R2. The first mask layer ML1 may be a layer that can be removed, for example, by an ashing process, and may be a photomask layer, but the inventive concept is not limited thereto.

Referring to FIG. 8H, the first conductive layer 172 and the gate dielectric layer 162 exposed through the first mask layer ML1 may be removed.

The first conductive layer 172 and the gate dielectric layer 162 exposed by the opening OP of the first mask layer ML1 may be removed by a wet etching process and/or a dry etching process. Accordingly, the device isolation layer 110 may be exposed through the opening OP.

In this process, a thickness of the first conductive layer 172, etched and removed, may be relatively small, for example, about 5 nm or less. Accordingly, for example, as compared to the example in which the gate isolation layer 180 is formed after the third conductive layer 176 (see FIG. 2B) is formed, the opening OP may be formed by removing a smaller amount of a conductive material, such that the etching process may be performed easily.

Referring to FIG. 8I, a preliminary gate isolation layer 180P filling the opening OP may be formed.

The preliminary gate isolation layer 180P may form the gate isolation layer 180 (see FIG. 2B) through a subsequent process. The preliminary gate isolation layer 180P may be an insulating layer and may include a single layer or a plurality of layers. For example, the preliminary gate isolation layer 180P may be a SiN layer.

Referring to FIG. 8J, the gate isolation layer 180 may be formed by partially removing the preliminary gate isolation layer 180P.

The gate isolation layer 180 may be partially removed from an upper surface by, for example, an etch-back process. Alternatively, the gate isolation layer 180 may be removed by preferentially performing chemical mechanical polishing (CMP) and performing an etch-back process. The gate isolation layer 180 in this process may have a height higher than the one in a final structure.

Differently from the example embodiment, when the gate isolation layer 180 is formed by partially removing the sacrificial gate structure 200 in FIG. 8C, when the sacrificial gate structure 200 is subsequently removed after forming the gate isolation layer 180, in a region adjacent to the gate isolation layer 180, the sacrificial gate structure 200 may remain without being completely removed. Differently from the example embodiment, when the gate isolation layer 180 is formed after the entirety of the first and second gate electrodes 170A and 170B in FIG. 2B are formed, the amount of etching of the conductive layer may be large as described above, such that process difficulty may increase, and the first and second gate electrodes 170A and 170B may be damaged. In the example embodiment, by forming the gate isolation layer 180 after the first conductive layer 172 is formed and before the second conductive layer 174 is formed, the processes may be easily performed without defects.

Referring to FIG. 8K, the first mask layer ML1 may be removed.

The first mask layer ML1 may be selectively removed by a cleaning process such as an ashing process and a strip process.

Referring to FIG. 8L, the second mask layer ML2 may be formed on the second region R2, and the first conductive layer 172 may be removed on the first region R1.

The second mask layer ML2 may be formed to cover the second region R2 and to expose the first region R1. For example, one end of the second mask layer ML2 may be disposed on the gate isolation layer 180. The second mask layer ML2 may be, for example, a photomask layer. The first conductive layer 172 on the first region R1 may be selectively removed, for example, by a wet etching process.

Referring to FIG. 8M, the sacrificial layer HM may be further removed from the first region R1.

The sacrificial layer HM may be selectively removed, for example, by a wet etching process. Accordingly, on the first region R1, the gate dielectric layers 162 may be exposed through the upper portion gap region UR and the lower gap regions LR.

Thereafter, the second mask layer ML2 may be removed. However, in some example embodiments, the sacrificial layer HM may be removed after removing the second mask layer ML2.

Referring to FIG. 8N, a second conductive layer 174 may be formed on the entire first and second regions R1 and R2.

The second conductive layer 174 may be deposited to a substantially uniform thickness on the gate dielectric layers 162 on the first region R1 and on the first conductive layer 172 on the second region R2. The second conductive layer 174 may be formed to fill a portion of the upper portion gap region UR. The second conductive layer 174 may extend along side surfaces and an upper surface of the gate isolation layer 180. In an example embodiment, the relative thicknesses of first and second conductive layers 172 and 174 may vary.

Thereafter, referring to FIGS. 2A and 2B, a third conductive layer 176, gate capping layers 166, and contact plugs 195 may be formed.

The third conductive layer 176 may be deposited on the second conductive layer 174. The third conductive layer 176 may be formed by further performing a planarization process after the deposition process. The third conductive layer 176 may be formed to completely fill the upper portion gap region UR. By the planarization process, an upper surface of the gate isolation layer 180 may be exposed, and an upper surface of the gate isolation layer 180 and an upper surface of the third conductive layer 176 may be coplanar with each other. In some example embodiments, the third conductive layer 176 may include a plurality of conductive layers. Accordingly, finally, the first and second gate electrodes 170A and 170B may be formed.

The gate capping layers 166 may be formed by removing a portion of the first and second gate electrodes 170A and 170B, the gate dielectric layers 162, the first and second gate spacer layers 163 and 164, and the gate isolation layer 180, filling the removed regions with an insulating material, and performing a planarization process. The relative thickness of the gate capping layers 166 and the shape of the lower surface thereof may vary in example embodiments.

Thereafter, the interlayer insulating layer 190 may be additionally formed, and the contact plugs 195 electrically connected to (e.g., contacting) the first and second source/drain regions 150A and 150B may be formed. Accordingly, the semiconductor device 100 in FIGS. 1 to 2B may be manufactured.

According to the aforementioned example embodiments, by forming a gate isolation layer after the first conductive layer is formed and before the second conductive layer is formed, a semiconductor device having improved reliability and mass productivity may be provided.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the example embodiments have been illustrated and described above, it will be apparent to those skilled in the art that modifications and variations may be made without departing from the scope in the invention as defined by the appended claims.

What is claimed is:

1. A semiconductor device, comprising:
a substrate having a first region and a second region;
a first active region extending in a first direction on the first region;
a second active region extending in the first direction on the second region;
a device isolation layer defining the first and second active regions in the substrate;
a first gate electrode crossing the first active region and extending in a second direction;
a second gate electrode crossing the second active region and extending in the second direction;
a plurality of first channel layers spaced apart from each other in a third direction perpendicular to an upper surface of the substrate and surrounded by the first gate electrode on the first active region;
a plurality of second channel layers spaced apart from each other in the third direction and surrounded by the second gate electrode on the second active region;
gate insulating layers between the plurality of first channel layers and the first gate electrode and between the plurality of second channel layers and the second gate electrode; and
a gate isolation layer between the first gate electrode and the second gate electrode, the gate isolation layer including an insulating material,
wherein the second gate electrode includes a first conductive layer and a second conductive layer stacked in order from the plurality of second channel layers,
wherein the first gate electrode includes the second conductive layer covering the plurality of first channel layers and is spaced apart from the first conductive layer, and
wherein each of first and second side surfaces of the gate isolation layer in the second direction is in contact with the second conductive layer.

2. The semiconductor device of claim 1, wherein the second side surface of the gate isolation layer is in contact with the first conductive layer in a lower portion of the gate isolation layer.

3. The semiconductor device of claim 1, wherein the second conductive layer extends horizontally from the first and second side surfaces of the gate isolation layer along an upper surface of the device isolation layer.

4. The semiconductor device of claim 3, wherein the second conductive layer has substantially the same thickness on the first and second side surfaces of the gate isolation layer and on the upper surface of the device isolation layer.

5. The semiconductor device of claim 1,
wherein the first conductive layer fills a space between the plurality of second channel layers, and
wherein the second conductive layer fills a space between the plurality of first channel layers.

6. The semiconductor device of claim 1, wherein the first gate electrode further includes a third conductive layer on the second conductive layer and between the gate isolation layer and the plurality of first channel layers in the second direction.

7. The semiconductor device of claim 6, wherein the second gate electrode further includes the third conductive layer disposed on the second conductive layer and disposed between the gate isolation layer and the plurality of second channel layers in the second direction.

8. The semiconductor device of claim 1, wherein the gate insulating layers are isolated from each other by the gate isolation layer and are in contact with the first and second side surfaces of the gate isolation layer in a lower portion of the gate isolation layer, respectively.

9. The semiconductor device of claim 1, wherein the first gate electrode does not include the first conductive layer.

10. The semiconductor device of claim 1, wherein an upper surface of the gate isolation layer is coplanar with an upper surface of the first gate electrode and an upper surface of the second gate electrode.

11. The semiconductor device of claim 1, wherein the gate isolation layer is configured as a single layer formed of an insulating material.

12. The semiconductor device of claim 1, wherein a lower surface of the gate isolation layer is on a level lower than a level of upper surfaces of the first and second active regions.

13. The semiconductor device of claim 1, wherein the first active region and the second active region include impurities of different conductivity types.

14. A semiconductor device, comprising:
a first active region and a second active region extending in a first direction on a substrate, spaced apart from each other in a second direction intersecting the first direction, the first and second active regions including impurities of different conductivity types from each other;
a first gate electrode crossing the first active region and extending in the second direction;
a second gate electrode crossing the second active region and extending in the second direction; and
a gate isolation layer between the first and second gate electrodes,
wherein the second gate electrode includes a first conductive layer and a second conductive layer stacked in order,
wherein the first gate electrode includes the second conductive layer and is spaced apart from the first conductive layer,
wherein a first side surface of the gate isolation layer in the second direction faces the first gate electrode and is in contact with the second conductive layer, and
wherein a second side surface opposing the first side surface of the gate isolation layer faces the second gate electrode and is in contact with the first conductive layer and the second conductive layer in order from a lower portion of the gate isolation layer.

15. The semiconductor device of claim 14, wherein a first height of a first portion of the second side surface in contact with the first conductive layer is less than a second height of a second portion of the second side surface in contact with the second conductive layer.

16. The semiconductor device of claim 15, wherein the second height is 10 times the first height or more.

17. The semiconductor device of claim 14, wherein the first conductive layer and the second conductive layer have different compositions.

18. The semiconductor device of claim 14, further comprising:
a gate insulating layer between the first active region and the first gate electrode,
wherein the first side surface is entirely covered by the gate insulating layer and the second conductive layer.

19. A semiconductor device, comprising:
a first active region and a second active region extending in a first direction on a substrate, spaced apart from each other in a second direction intersecting the first direction, the first and second active regions including impurities of different conductivity types from each other;
a first gate electrode crossing the first active region and extending in the second direction;
a second gate electrode crossing the second active region and extending in the second direction; and
a gate isolation layer between the first and second gate electrodes,
wherein the second gate electrode includes a first conductive layer, a second conductive layer, and a third conductive layer stacked in order,
wherein the first gate electrode includes the second conductive layer and the third conductive layer stacked in order, and is spaced apart from the first conductive layer, and
wherein each of side surfaces of the gate isolation layer in the second direction is in contact with the second conductive layer and is spaced apart from the third conductive layer.

20. The semiconductor device of claim 19, wherein the second conductive layer extends only to upper ends of the side surfaces of the gate isolation layer to not cover an upper surface of the gate isolation layer.
